(19) United States
(12) Patent Application Publication
(10) Pub. No.: US 2009/0293803 A1
(43) Pub. Date: Dec. 3, 2009

(54) Method of growing silicon single crystals

(76) Inventors: Takanori Tsurumaru, Tokyo (JP); Hideki Hara, Tokyo (JP); Ryoichi Kaito, Tokyo (JP)

Correspondence Address: CLARK & BRODY, 1090 VERMONT AVENUE, NW, SUITE 250, WASHINGTON, DC, 20005, US

(21) Appl. No.: 12/457,066

(22) Filed: Jun. 1, 2009

(30) Foreign Application Priority Data
Jun. 3, 2008 (JP) 2008-145674

(51) Int. Cl. C30B 15/22

(52) U.S. Cl. 117/35; 117/11

(57) ABSTRACT

By providing a length of not less than 100 mm to a tail portion to be formed following the cylindrical body portion in growing silicon single crystals having a cylindrical body portion with a diameter of 450 mm using the CZ method, it becomes possible to inhibit the occurrence of dislocations in the tail portion and thus achieve improvements in yield and productivity. A transverse magnetic field having an intensity of not less than 0.1 T is preferably applied on the occasion of formation of that tail portion.

### BACKGROUND OF THE INVENTION

1. Field of the Invention

The present invention relates to a method of growing silicon single crystals using the Czochralski method (hereinafter referred to as “CZ method”) and, more particularly, to a method of growing silicon single crystals which is suited for growing large-diameter silicon single crystals having a cylindrical body portion with a diameter of 450 mm.

2. Description of the Related Art

Silicon single crystals are source materials for manufacturing silicon wafers to be used in semiconductor devices, and single crystal growing processes based on the CZ method are in wide use for the production thereof. According to the CZ method, silicon single crystals are generally grown in the following manner.

In a pulling apparatus in which an inert gas atmosphere is maintained under reduced pressure, silicon raw materials placed in a quartz crucible are heated and melted by means of a heater, and a seed crystal is immersed into the silicon melt. The seed crystal is then slowly pulled up from this condition, accompanying a silicon single crystal grown at the lower of the seed crystal.

FIG. 1 is a schematic representation of a grown silicon single crystal. In the process of growing the silicon single crystal 11, a neck portion 11a reduced in diameter is first formed from the seed crystal 7 so that those dislocations introduced from heat shock upon contact of the seed crystal 7 with the silicon melt may be removed. Then, a cone-shaped shoulder portion 11b successively increasing in diameter to a desired diameter D is formed and, thereafter, a cylindrical body portion 11c with the desired diameter D, which is to serve as a product for manufacturing silicon wafers, is formed. And, in the final stage of growing, a reverse cone-shaped tail portion 11d resulting from gradual reduction in diameter from the cylindrical body portion 11c is formed for preventing dislocations from being introduced.

Here, in this tail portion 11d, dislocations are likely to occur as a result of abrupt change in temperature on the occasion of separation from the silicon melt. Therefore, in the conventional mode of operation, the tail portion 11d is given a length L which is more than the diameter D of the cylindrical body portion 11c so that such dislocations may be prevented from extending to the cylindrical body portion 11c even in the case of occurrence of such dislocations in the tip of the tail portion 11d.

Regarding the length of the tail portion to be formed, Japanese Patent Application Publication No. 2007-284313 proposes a silicon single crystal such that the tail portion thereof is constituted of a tapered portion and a terminal portion, in which the length of the tapered portion should be not less than the half of the diameter of the cylindrical body portion and the terminal portion should be given a length of not less than the minimum diameter of the tapered portion. It is alleged that, in the silicon single crystal proposed in the above-cited document, the occurrence of dislocations in the tapered portion and the extension of those dislocations that have occurred in the tip of the terminal portion can be prevented by defining the lengths of the tapered portion and the terminal portion constituting the tail portion.

### SUMMARY OF THE INVENTION

In accordance with the recent demands for cost reduction and improved productivity, attempts have been made in the art to increase the diameter of the cylindrical body portion of silicon single crystals; thus, commercialization of silicon single crystals having a diameter of 450 mm in lieu of those which are currently used and have a diameter of 300 mm is rigorously studied and under way.

However, in the case of growing silicon single crystals having a cylindrical body portion with a diameter of 450 mm (hereinafter also referred to as “silicon single crystals having a diameter of 450 mm” for short), the tail portion will have a length of not less than 450 mm when the tail portion is formed under the conventional operation conditions mentioned above, or will have a length exceeding 225 mm even when the tail portion is formed under the conditions proposed in the above-cited Japanese Patent Application Publication No. 2007-284313. Thus, the tail portion becomes elongated in either case. Accordingly, the cylindrical body portion, the product, of each silicon single crystal is shortened, raising such problems as reduction in product yield relative to the silicon raw materials and hindrance to improvement in productivity.

In this regard, the reduction in yield may be prevented and the productivity may be improved if the tail portion length is reduced; however, this may possibly cause the occurrence of dislocations during the formation of the tail portion.

The present invention has been made in view of such situations as mentioned above, and an object thereof is to provide a method of growing silicon single crystals according to which method the occurrence of dislocations can be inhibited and improvements of yield and productivity can be achieved by specifying the tail portion length in growing silicon single crystals having a diameter of 450 mm by the CZ method.

To accomplish the above object, the present inventors made investigations concerning the conditions for growing silicon single crystals having a diameter of 450 mm and, as a result, obtained the following findings.

On the occasion of tail portion formation, adjustments are generally made to raise the temperature of the silicon melt (hereinafter referred to as “melt temperature”) and, at the same time, increase the speed of pulling up the silicon single crystal (hereinafter referred to as “pulling speed”); when the increase in melt temperature and/or pulling speed is too sharp, however, dislocations may occur at the crystal growth interface or, in some cases, the tail portion may be detached from the silicon melt during tail portion formation, resulting in occurrence of dislocations. When, on the contrary, the tail portion to be formed is surely given a length of 100 mm or more, the melt temperature and pulling speed can be controlled without any abrupt change and the tail portion gradually reduced in diameter can be formed and, as a result, dislocations can be inhibited from occurring.

For inhibiting dislocations from occurring more effectively on the occasion of tail portion formation, it is effective to apply a transverse magnetic field to the silicon melt. The application of such a transverse magnetic field inhibits the convection of the silicon melt and suppress abrupt change in melt temperature at the crystal growth interface, so that the tail portion is likely formed in a manner such that the diameter thereof is reduced gradually.

The gist of the present invention, which has been made based on those findings, consists in the following method of growing silicon single crystals. Namely, it consists in a method of growing silicon single crystals which is characterized in that, on the occasion of growing silicon single crystals having a cylindrical body portion with a diameter of 450 mm by the CZ method, the tail portion to be formed following the cylindrical body portion is given a length of not less than 100 mm.

The term “diameter of 450 mm” as used herein means that the cylindrical body portion, which is an expected product, can give silicon wafers having a diameter of 450 mm after external surface machining, slicing, polishing, heat treatment and so forth; hence, the single crystal in an as-grown condition may sometimes have a diameter up to a maximum of about 460-470 mm.

In carrying out this method of growing silicon single crystals, a transverse magnetic field can be applied on the occasion of the above-mentioned tail portion formation. In this case, the transverse magnetic field preferably has an intensity of not less than 0.1 T (tesla).

In accordance with the method of growing silicon single crystals according to the present invention, it is possible to form a tail portion gradually reduced in diameter on the occasion of growing silicon single crystals having a diameter of 450 mm by the CZ method by specifying the tail portion length at a level of 100 mm or more and, as a result, it becomes possible to inhibit dislocations from occurring in the tail portion. In addition, the tail portion length can be reduced as compared with the case of tail portion formation under the conventional operation conditions or the conditions proposed by Japanese Patent Application Publication No. 2007-284313; thus, it becomes possible to achieve a yield improvement and increase productivity.

### BRIEF DESCRIPTION OF THE DRAWINGS

FIG. 1 is a schematic representation of a grown silicon single crystal.

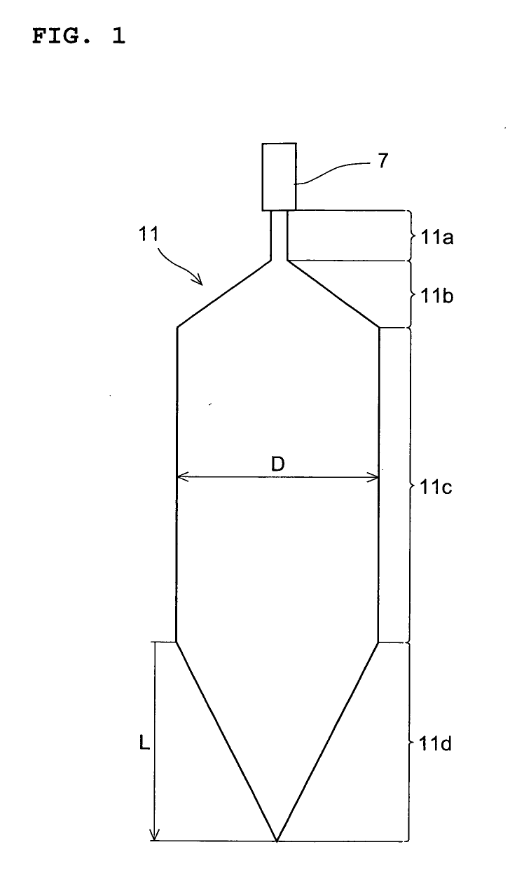

FIG. 2 is a schematic representation of the configuration of a single crystal pulling apparatus suited for growing silicon single crystals having a diameter of 450 mm by the CZ method.

FIG. 3 is a schematic representation of a grown silicon single crystal having a diameter of 450 mm.

### DETAILED DESCRIPTION OF THE PREFERRED EMBODIMENTS

In the following, a mode of embodiment of the method of growing silicon single crystals according to the present invention is described in detail. The method of growing silicon single crystals in this mode of embodiment is characterized in that, on the occasion of growing silicon single crystals having a cylindrical body portion with a diameter of 450 mm by the CZ method, a tail portion to be formed following the cylindrical body portion is given a length of 100 mm or more.

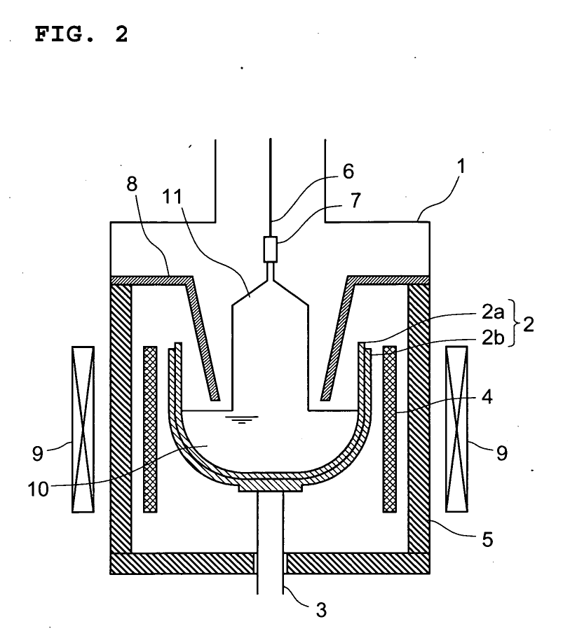

FIG. 2 is a schematic representation of the configuration of a single crystal pulling apparatus suited for growing silicon single crystals having a diameter of 450 mm by the CZ method. As shown in the figure, the single crystal pulling apparatus comprises a chamber 1, constituting the outer shell thereof, and a crucible 2 in the central part thereof. The crucible 2 has a double structure which consists of an inner quartz crucible 2a and an outer graphite crucible 2b, and is fixed to the upper end of a supporting shaft 3 which is rotatable and movable upward or downward.

Outside the crucible 2, there is disposed a resistance heating type heater 4 surrounding the crucible 2 and, further outside the same, there is disposed a thermal insulator 5 along the internal surface of the chamber 1. Above the crucible 2 is disposed a pulling line 6 comprising a wire capable of rotating at a predetermined speed in the reverse or the same direction relative to the supporting shaft 3 on the same axis, and a seed crystal 7 is fixed to the lower end of this pulling line 6.

Further, within the chamber 1, a cylindrical heat shield 8 surrounding the silicon single crystal 11 during pulling up thereof is disposed for shielding the radiation heat from the silicon melt 10 in the crucible 2 and from the heater 4. Outside the chamber 1, there is also disposed a pair of magnetic coils 9 for applying a transverse magnetic field, in a horizontal direction, to the silicon melt 10 in the crucible 2.

In growing silicon single crystals with a diameter of 450 mm using such a single crystal pulling apparatus, silicon raw materials such as polycrystalline silicon are placed in the crucible 2, and the materials are heated and melted in the crucible 2 by means of the heater 4 in an inert gas atmosphere under reduced pressure. After formation of the silicon melt 10 in the crucible 2, the pulling line 6 is caused to descend and the seed crystal 7 is immersed into the surface layer of the silicon melt 10. From this state, the pulling line 6 is caused to gradually ascend while the crucible 2 and the pulling line 6 are rotated in respectively predetermined directions, whereby a silicon single crystal 11 is grown at the lower end of the seed crystal 7.

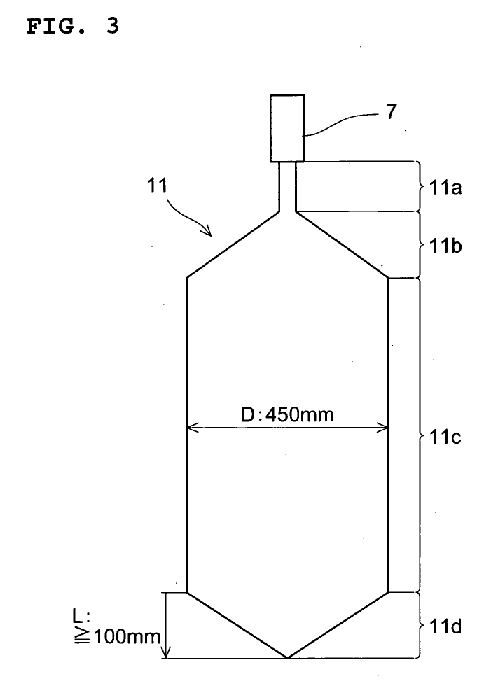

FIG. 3 is a schematic representation of a grown silicon single crystal having a diameter of 450 mm. In the process of growing the silicon single crystal 11, a neck portion 11a is formed so as to be linked end to end with the bottom of the seed crystal 7, a cone-shaped shoulder portion 11b successively increasing in diameter to the diameter D of 450 mm is then formed and, thereafter, a cylindrical body portion 11c, which has the diameter D of 450 mm and is to serve as a product for manufacturing silicon wafers, is formed. And, an inverted cone-shaped tail portion 11d gradually reduced in diameter from the cylindrical body portion 11c is formed.

In this mode of embodiment, on the occasion of formation of the tail portion 11d, the output of the heater 4 shown in FIG. 2 is increased to thereby raise the temperature of the silicon melt and, simultaneously, the pulling speed is increased to form a tail portion 11d so that it may have a length L of not less than 100 mm. By giving a length L of not less than 100 mm to the tail portion 11d, it becomes possible to control the melt temperature and pulling speed without any abrupt changes. Thereby, it becomes possible to form the tail portion 11d gradually reduced in diameter and, as a result, to inhibit dislocations from occurring.

Furthermore, by giving a length L of not less than 100 mm to the tail portion 11d, it becomes possible to reduce the tail portion length as compared with the case of tail portion formation under the conventional operation conditions or under the conditions proposed in Japanese Patent Application Publication No. 2007-284313; thus, it becomes possible to achieve a yield improvement and increase productivity.

The upper limit of the length L of the tail portion 11d is not particularly prescribed herein but, from the viewpoint of possible yield reduction it is preferably set at about 500-600 mm, more preferably at 200 mm or less.

The tail portion 11d can also be formed under application of a transverse magnetic field to the silicon melt in the crucible by means of the magnetic coils 9 shown in FIG. 2. The application of a transverse magnetic field retards the convection of the silicon melt and, therefore, sudden change in melt temperature at the crystal growth interface is suppressed, so that the tail portion 11d is formed while gradually decreasing in diameter, with the result that the occurrence of dislocations can be inhibited more effectively.

In that case, the magnetic flux density of the transverse magnetic field to be applied is preferably not less than 0.1 T (tesla). The intensity of the transverse magnetic field should be not less than 0.1 T since, at levels below 0.1 T, the effect of inhibiting the convection of the silicon melt cannot be produced to a satisfactory extent. The upper limit of the transverse magnetic field intensity is not particularly prescribed herein but, from a viewpoint of the equipment designing, it is preferably set at 0.7 T or less since when an excessively intense transverse magnetic field is employed, the equipment for magnetic field application becomes large in size and the electric power consumption increases.

Such a transverse magnetic field can also be applied not only in the step of formation of the tail portion lid but also in the preceding step of formation of the cylindrical body portion 11c and/or the shoulder portion 11b, for instance, since it becomes possible to homogenize the dopant and impurity concentration distribution at the crystal growth interface as a result of inhibition of the convection of the silicon melt as caused by application of the transverse magnetic field and, accordingly, it becomes possible to improve the quality of the silicon single crystals.

### EXAMPLES

For confirming the effects of the method of growing silicon single crystals according to the present invention, a numerical analysis was carried out if dislocations should occur or not. The case assumed in the numerical analysis was such that a crucible having an inside diameter of 40 inches was used in the single crystal pulling apparatus shown in FIG. 2, a transverse magnetic field of 0.1 T was applied, and silicon single crystals having a total weight of 1000 kg and a diameter of 450 mm were grown. The numerical analysis was carried out under such conditions that the tail portion length was varied as follows: 50 mm, 80 mm, 100 mm, 200 mm and 500 mm.

As a result, the occurrence of dislocations was appreciated when the tail portion length was 50 mm or 80 mm, whereas no occurrence of dislocations was found when the tail portion length was 100 mm, 200 mm or 500 mm. Thus, it can be said that when the tail portion length is not less than 100 mm in growing silicon single crystals with a diameter of 450 mm, dislocations can be inhibited from occurring.

The method of growing silicon single crystals according to the present invention makes it possible to form the tail portion gradually reduced in diameter by specifying the tail portion length at a level of 100 mm or longer in growing silicon single crystals with a diameter of 450 mm using the CZ method; as a result, it becomes possible to inhibit dislocations from occurring in the tail portion. In addition, the tail portion length can be shortened and, therefore, it becomes possible to achieve improvements in yield and productivity. Thus, the present invention is very useful in putting large-diameter silicon single crystals having a diameter of 450 mm into practical use.

What is claimed is:

1. A method of growing silicon single crystals having a cylindrical body portion with a diameter of 450 mm using the Czochralski method, comprising providing a length of not less than 100 mm to a tail portion to be formed following cylindrical body portion.

2. The method of growing silicon single crystals according to claim 1, wherein a transverse magnetic field is applied on the occasion of formation of the tail portion.

3. The method of growing silicon single crystals according to claim 2, wherein the transverse magnetic field has an intensity of not less than 0.1 T (tesla).
